(19) United States
(12) Patent Application Publication
(10) Pub. No.: US 2015/0200177 A1
(43) Pub. Date: Jul. 16, 2015

(54) WAFER LEVEL PACKAGE WITH REDISTRIBUTION LAYER FORMED WITH METALLIC POWDER

(71) Applicants: CHEE SENG FOONG, Sg. Buloh (MY); Lan Chu Tan, Singapore (SG)

(72) Inventors: CHEE SENG FOONG, Sg. Buloh (MY); Lan Chu Tan, Singapore (SG)

(21) Appl. No.: 14/151,833

(22) Filed: Jan. 10, 2014

(51) Int. Cl. H01L 23/00; H01L 23/498

(52) U.S. Cl. CPC H01L 24/27; H01L 23/49816; H01L 24/06; H01L 24/13; H01L 2224/27332; H01L 2224/27505; H01L 2224/0401; H01L 2224/06138

(57) ABSTRACT

A semiconductor device is assembled where a signal redistribution layer is formed over a partially encapsulated semiconductor die. The distribution layer is formed by selectively coating a first electrical insulating layer over an active surface of the die and a surrounding portion of the encapsulation material, where die bonding pads on the active surface of the die are exposed through access apertures in the first electrical insulating layer. A layer of metallic powder is deposited onto the first insulating layer and then electrically conductive runners are formed from the layer of metallic powder. The runners are coated with a further electrical insulating layer. A mounting area of each runner is exposed through an external connection aperture. Solder balls may be attached to the mounting areas.

### BACKGROUND OF THE INVENTION

The present invention relates generally to semiconductor packaging and, more particularly, to wafer level package having a redistribution layer formed with metallic powder.

Packaged semiconductors provide external electric connections and physical protection for packaged dies. Continued progress in reduction of the size of the semiconductor dies and increased functionality and complexity of the integrated circuits of the dies requires size reduction of the packaging with the same or greater complexity of the electrical connections with external circuits.

One typical type of packaged semiconductors is Quad Flat Pack (QFP) packages, which are formed with a semiconductor die mounted to a lead frame. The lead frame is formed from a sheet of metal that has a die attach pad often called a flag and leads or lead fingers that attach the flag to a frame. The lead fingers are connected to electrodes of the die with bond wires to provide a means of easily electrically connecting the die to circuit boards and the like. The die and lead frame are encapsulated in a plastic material leaving only sections of the leads exposed. These exposed leads are cut from the frame of the lead frame (singulated) and bent for ease of connection to a circuit board. However, the inherent structure of QFP packages results in limiting the number of leads, and therefore the number of package external electrical connections that can be used for a specific QFP package size. Further, the external electrical connections of the lead frame based grid array packages are typically fabricated from a thin single sheet of conductive material, such as copper or aluminium, and these connections may not be sufficiently held within the encapsulating material and may become loose.

Wafer level chip scale packages, such as grid array packages have been developed as an alternative to QFP packages. Grid array packages increase the number of external electrical connections while maintaining or even decreasing the package size. Such grid array packages include Pin Grid Arrays (PGA), Ball Grid Array (BGA) and Land Grid Arrays (LGA). The assembly of such packages requires numerous masking, depositing and etching steps, which are relatively time consuming and costly.

### BRIEF DESCRIPTION OF THE DRAWINGS

The invention, together with objects and advantages thereof, may best be understood by reference to the following description of preferred embodiments together with the accompanying drawings in which:

FIG. 1 is a plan view of part of a sheet of partially formed packages in accordance with a preferred embodiment of the present invention;

FIG. 2 is a cross-sectional side view through 2-2′ of the sheet of FIG. 1 showing a single partially formed package, in accordance with a preferred embodiment of the present invention;

FIG. 3 is a cross-sectional side view of a coated partially formed package formed from the partially formed package of FIG. 2, in accordance with a preferred embodiment of the present invention;

FIG. 4 is a cross-sectional side view of a powder covered partially formed package formed from the coated partially formed package of FIG. 3, in accordance with a preferred embodiment of the present invention;

FIG. 5 is a cross-sectional side view of a processed assembly formed from the package of FIG. 4, in accordance with a preferred embodiment of the present invention;

FIG. 6 is a cross-sectional side view of a further processed assembly formed from the processed assembly of FIG. 5, in accordance with a preferred embodiment of the present invention;

FIG. 7 is a cross-sectional side view of a selectively coated un-singulated semiconductor device formed from the assembly of FIG. 6, in accordance with a preferred embodiment of the present invention;

FIG. 8 is a cross-sectional side view of a selectively coated un-singulated ball grid array package formed from the semiconductor device of FIG. 7, in accordance with a preferred embodiment of the present invention;

FIG. 9 is a cross-sectional side view of a semiconductor device formed from the un-singulated semiconductor device of FIG. 8, in accordance with a preferred embodiment of the present invention;

FIG. 10 is a cross-sectional side view of a semiconductor device formed from the un-singulated semiconductor device of FIG. 7, in accordance with another preferred embodiment of the present invention;

FIG. 11 is a cross-sectional side view of a semiconductor device formed from the un-singulated semiconductor device of FIG. 7, in accordance with a further preferred embodiment of the present invention; and

FIG. 12 is a flow chart illustrating a method for assembling a semiconductor device according to a preferred embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step. The term semiconductor device, as used herein, refers to a packaged semiconductor die.

In one embodiment, the present invention provides a method of assembling a semiconductor device. The method comprises providing a partially formed package that includes a semiconductor die and an encapsulating region. A support surface of the partially formed package includes an active surface of the die and an adjacent surface of the encapsulating region. Selectively coating of the support surface with a first electrical insulating layer is performed, with bonding pads on the active surface of the die being exposed through access apertures in the first electrical insulating layer. A layer of metallic powder is deposited onto the first electrical insulating layer such that the powder fills the access apertures. Electrically conductive runners are formed from the layer of metallic powder. The runners are selectively connected to the die bonding pads through the access apertures. Regions of the layer of metallic powder that do not form the runners are then removed. The runners are then selectively coated with a further electrical insulating layer such that a mounting area of each runner is exposed through an external connection aperture in the further electrical insulating layer.

In another embodiment, the present invention provides a semiconductor device comprising a semiconductor die and an encapsulating substrate that together form a support surface. The support surface includes an active surface of the die and an adjacent surface of the encapsulating substrate. A first electrical insulating layer selectively coats the support surface so that bonding pads on the active surface of the die are exposed through access apertures in the first electrical insulating layer. Electrically conductive runners are respectively connected to the die bonding pads through the access apertures and insulated from the active surface by the first electrical insulating layer. The runners are formed from a metallic powder deposit. A further electrical insulating layer coats the runners such that a mounting area of each runner is exposed through an external connection aperture in the further electrical insulating layer.

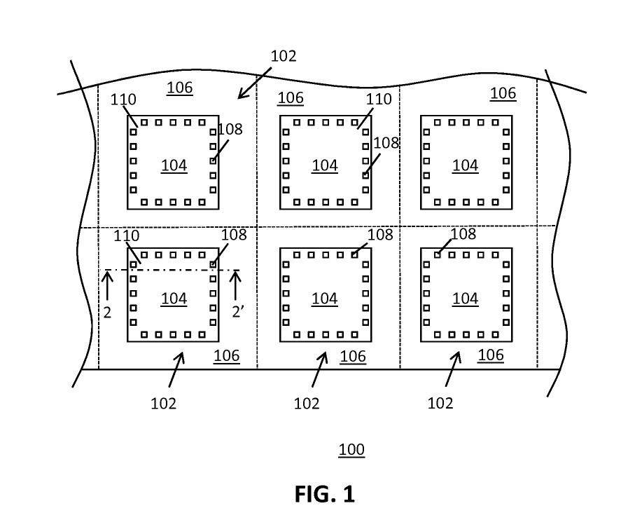

Referring now to FIG. 1, there is illustrated a plan view of part of a sheet 100 of partially formed packages 102, in accordance with a preferred embodiment of the present invention. Each of the partially formed packages 102 includes a semiconductor die 104 (typically a silicon based die) and a surrounding encapsulating region 106 of the sheet 100. Each die 104 has bonding pads 108 on its active surface 110. The sheet 100 is typically formed from a conventional encapsulating material by a press moulding process. During the press moulding process the encapsulating material (an insulating compound) is press moulded to form recesses in the sheet 100 that encapsulate each die 104. Consequently, each encapsulating region 106 is an encapsulating substrate for one of the partially formed packages 102.

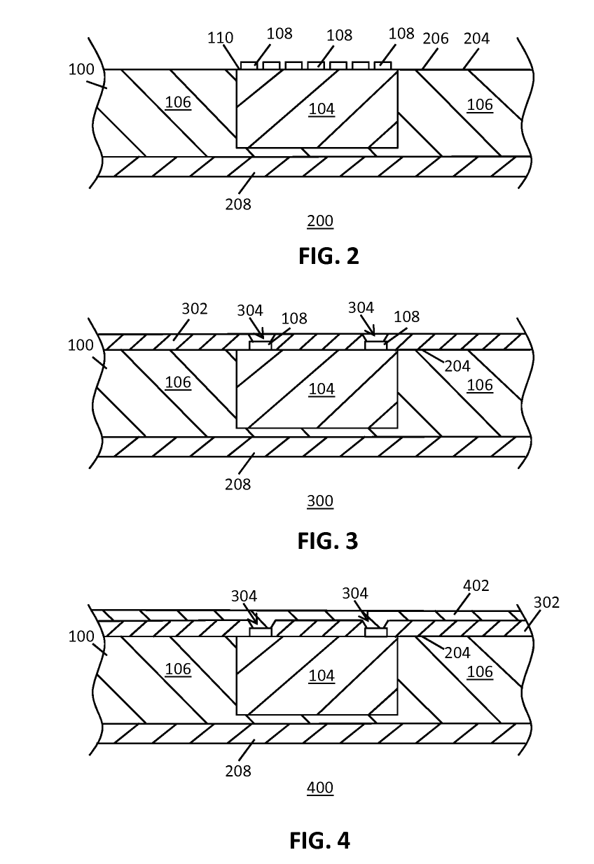

FIG. 2 is a cross-sectional side view through 2-2′ of the sheet 100 that shows a single partially formed package 200, in accordance with a preferred embodiment of the present invention. In this illustration the single partially formed package 200 has a support surface 204 that includes the active surface 110 of the die 104 and an adjacent surface 206 of the encapsulating region 106. In this embodiment, the active surface 110 of the die 104 and the adjacent surface 206 of the encapsulating region 106 are co-planar, however, in other embodiments the active surface 110 and adjacent surface 206 of the encapsulating region 106 need not necessarily be co-planar. The sheet 100 and thus the partially formed package 200 are supported by a support base 208 that is used as a carrier for transportation of the sheet 100 during assembly of semiconductor devices as described below.

FIG. 3 is a cross-sectional side view of a coated partially formed package 300 formed from the partially formed package 200, in accordance with a preferred embodiment of the present invention. The coated partially formed package 300 has been processed so that the support surface 204 has been coated with a first electrical insulating layer 302 (a dielectric). The first electrical insulating layer 302 has been deposited by a process that involves coating the support surface 204 with a liquid dielectric. The liquid dielectric is then selectively cured with Ultra Violet (UV) light, directed laser energy or other means of energy transfer by way of raster scanning or area projection, except over areas of the bonding pads 108. Liquid dielectric on top of the bonding pads 108 remains uncured and can be washed away so that the bonding pads 108 on the active surface 110 of the die 104 are exposed through apertures 304 in the first electrical insulating layer 302.

FIG. 4 is a cross-sectional side view of a powder covered partially formed package 400 formed from the coated partially formed package 300, in accordance with a preferred embodiment of the present invention. As shown, a layer of metallic powder 402 has been deposited onto the first insulating layer 302 such that the powder 402 fills the access apertures 304 and covers an upper surface of the first electrical insulating layer 302.

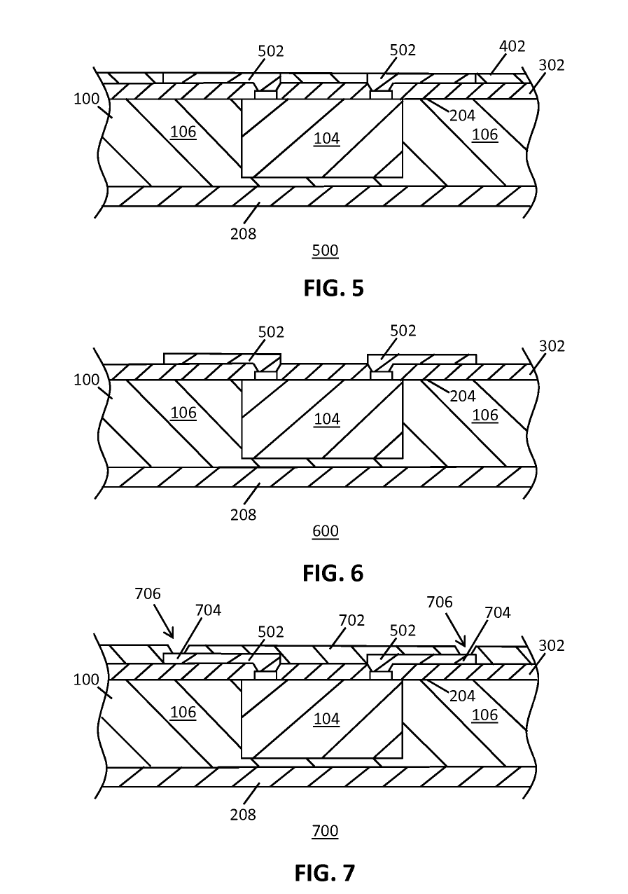

Referring to FIG. 5 there is illustrated a cross-sectional side view of a processed assembly 500 formed from the package 400, in accordance with a preferred embodiment of the present invention. The assembly 500 includes electrically conductive runners 502 that are selectively connected to the bonding pads 108 through the access apertures 304. The electrically conductive runners 502 are formed from the layer of metallic powder 402, which is selectively sintered or melted and subsequently solidified. In this embodiment the electrically conductive runners 502 are formed by a laser melting or sintering process of regions of the powder 402.

FIG. 6 is a cross-sectional side view of a further processed assembly 600 formed from the processed assembly 500, in accordance with a preferred embodiment of the present invention. The further processed assembly 600 has had excess regions, or remaining un-sintered regions, of the layer of metallic powder 402 removed from the support surface 206. The excess regions are areas of the metallic powder 402 that do not form the runners 502 and are thus removed from the support surface 206. The excess powder 402 may be removed by vacuuming or washing.

FIG. 7 is a cross-sectional side view of a selectively coated un-singulated semiconductor device or package 700 formed from the assembly 600, in accordance with a preferred embodiment of the present invention. The package 700 has a further electrical insulating layer 702 (dielectric) that selectively coats the runners 502 and exposed regions of the first electrical insulating layer 302. As shown, a mounting area 704 of each runner 502 is exposed through an external connection aperture 706 in the further electrical insulating layer to allow external connection of the package 700. The insulating layer 702 can be formed using UV or a laser beam in a raster scanning mode. The mounting area 704 can be exposed (the external connection aperture 706 formed) because when the UV or laser beam sweeps into that area, the beam is cut off. Alternatively, a reticle beam (area) where the beam is absent over the mounting area 704 may be used so that the liquid is not cured at the area 704 and thus may be easily removed such as by washing.

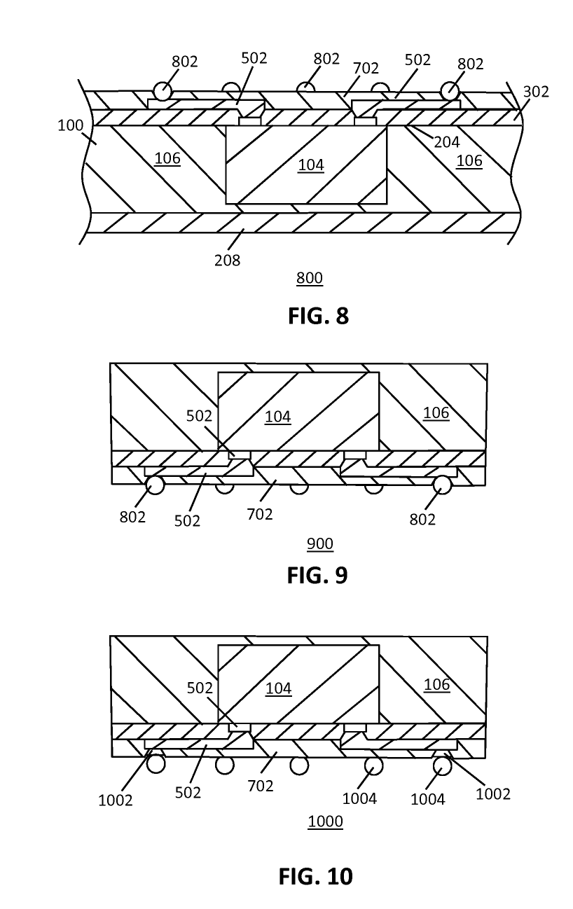

FIG. 8 is a cross-sectional side view of an un-singulated BGA package 800 formed from the package 700, in accordance with a preferred embodiment of the present invention. The BGA package 800 has solder balls 802 directly mounted to respective ones of the mounting areas 704 such that part of each solder ball 800 is located in an external connection aperture 706. Each solder ball 802 can be mounted (electrically attached) to a respective mounting area 704 by fluxing and a reflow process as will be apparent to a person skilled in the art.

FIG. 9 is a cross-sectional side view of a semiconductor device or package 900 formed from the un-singulated package 800, in accordance with a preferred embodiment of the present invention. Since the package 900 was integrally formed in the sheet 100 with other packages 900, the package 900 has been separated (singulated) from the sheet 100 by a cutting or punching process. The package 900 has been removed from support base 208 and has also been rotated such that each solder ball 802 forms a circuit board mount as will be apparent to a person skilled in the art. More specifically, the solder balls 802 form a ball grid array in which each solder ball 802 is electrically coupled via a runner 502 to one of the bonding pads 108 of the die 104.

Referring to FIG. 10, a cross-sectional side view of a semiconductor device or package 1000 formed from the package 700, in accordance with another preferred embodiment of the present invention, is illustrated. In this embodiment, a further layer of metallic powder is deposited in each external connection aperture 706 to form external electrically conductive mounting pads 1002. The pads 1002 are formed from the further layer of metallic powder by sintering or melting the powder and then allowing it to solidify. A solder ball 1004 is mounted to each of the external electrically conductive mounting pads 1002 by fluxing and a reflow process in a similar fashion to the process performed on the package 800.

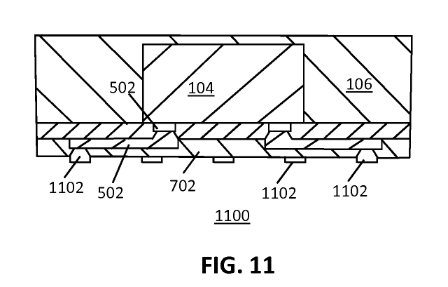

FIG. 11 is a cross-sectional side view of a semiconductor device or package 1100 formed from the package 700, in accordance with a further preferred embodiment of the present invention. In this embodiment a further layer of metallic powder is deposited over the further electrical insulating layer 702 such that the powder fills the external connection apertures 706. The metallic powder in and on top of each of the external connection apertures 706 is sintered or melted and solidified to form external electrically conductive mounting pads 1102. Excess powder is then removed such as by vacuuming so that the resulting each of the external electrically conductive mounting pads 1102 protrude out from a respective external connection aperture 706.

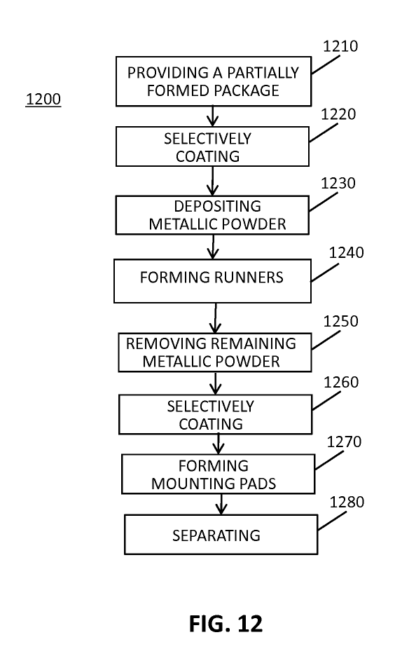

Referring to FIG. 12, a method 1200 of assembling a semiconductor device or package according to a preferred embodiment of the present invention is shown. For illustrative purposes the method 1200 will be described with reference to FIGS. 1 to 11, however, it is to be understood that the method 1200 is not limited to the embodiments specifically described in FIGS. 1 to 11.

At a providing block 1210 the partially formed package 200 is provided typically as part of the sheet 100. At a selectively coating block 1220 the support surface 204 is selectively coated with the first electrical insulating layer 302. Bonding pads 108 on the active surface 110 of the die 104 are exposed through the access apertures 304 in the first electrical insulating layer 302. As previously mentioned, excess powder and powder that is purposefully not melted may be removed by vacuuming or washing.

At a depositing block 1230 the layer of metallic powder 402 is deposited onto the first electrical insulating layer 302 so that the powder fills the access apertures 304. The depositing of the layer of metallic powder 402 is typically performed by a depositing and rolling process so that a planar upper powder layer surface is provided. The rolling process also reduces the possibility of unwanted voids in the layer of metallic powder 402. Next, at a forming block 1240, the electrically conductive runners 502 are formed from the layer of metallic powder such that the runners 502 are selectively connected to the bonding pads 108 through their respective access apertures 304. In one embodiment the runners 502 are formed by selective laser melting of the metallic powder. In another embodiment the runners 502 are formed by selective laser sintering process of the metallic powder followed by solidifying of the melted powder. Remaining metallic powder 402 (powder 402 that does not form the runners 502) that was not sintered or melted is removed by a vacuuming process at a removing block 1250. As will be apparent to a person skilled in the art, melting of the metallic powder will form almost full density solids. In contrast, sintering of the metallic powder requires a further baking step to solidify the sintered metallic powder.

A process of selectively coating is performed at a block 1260. The process of block 1260 coats at least the runners 502 with the further electrical insulating layer 702 such that the mounting area 704 of each runner 502 is exposed through their respective external connection aperture 706 in the further electrical insulating layer 702. At a forming block 1270, mounting pads are formed by the solder balls 802, which are mounted to a respective mounting area 704 such that part of each solder ball 800 is located in an external connection aperture 706. In another embodiment electrically conductive mounting pads 1002 are formed by depositing of the further layer of metallic powder in each external connection aperture 706. The further layer of metallic powder is then sintered or melted and solidified to form the electrically conductive mounting pads 1002. Solder balls 1004 are then mounted to their respective external electrically conductive mounting pads 1002 by fluxing and a reflow process. In yet a further embodiment, the electrically conductive mounting pads are formed by a depositing of a further layer of metallic powder over the further electrical insulating layer 702 so that the powder fills the external connection apertures 706. The metallic powder that is in and on top of each of the external connection apertures 706 is sintered or melted and solidified to form external electrically conductive mounting pads 1102. Excess powder is then removed so that the resulting each of the external electrically conductive mounting pads 1102 protrude out from a respective external connection aperture 706.

At a separating block 1280 each package is separated from the sheet 100 by a singulation process to form the semiconductor package 900, 1000 or 1100. The singulation process may comprise cutting, sawing or stamping, as is known in the art.

Advantageously, the present invention provides for assembling a semiconductor device without the need for a lead frame or numerous masking, depositing and etching processes. Also, if required, further depositing of insulating and metallic powder layers can be performed along with sintering or melting to form more elaborate conductive runner formations and grid array structures.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A method of assembling a semiconductor device, the method comprising:
providing a partially formed package including a semiconductor die and an encapsulating region, wherein a support surface of the partially formed package includes an active surface of the die and an adjacent surface of the encapsulating region;
selectively coating the support surface with a first electrical insulating layer so that bonding pads on the active surface of the die are exposed through access apertures in the first electrical insulating layer;
depositing a layer of metallic powder onto the first electrical insulating layer, wherein the powder fills the access apertures;
forming electrically conductive runners from the layer of metallic powder, the runners being selectively connected to the die bonding pads through the access apertures;
removing regions of the layer of metallic powder that do not form the runners; and
selectively coating the runners with a further electrical insulating layer so that a mounting area of each runner is exposed through an external connection aperture in the further electrical insulating layer, thereby forming the semiconductor device.

2. The method of claim 1, further comprising mounting a respective solder ball to each mounting area.

3. The method of claim 1, further comprising:
depositing a further layer of metallic powder in each external connection aperture; and
forming external electrically conducting mounting pads from the further layer of metallic powder.

4. The method of claim 3, further comprising mounting a respective solder ball to each of the external electrically conductive mounting pads.

5. The method of claim 3, wherein the external electrically conductive mounting pads protrude from the external connection apertures.

6. The method of claim 1, wherein the active surface of the die and the adjacent surface of the encapsulating region are co-planar.

7. The method of claim 1, wherein forming the electrically conductive runners is performed by selective laser sintering of the metallic powder.

8. The method of claim 1, wherein forming the electrically conductive runners is performed by a selective laser melting process of the metallic powder.

9. The method of claim 1, wherein the partially formed package is integrally formed in a sheet with other partially formed packages, and wherein the method includes separating the semiconductor device from the sheet.

10. The method of claim 1, wherein the package is a grid array package.

11. A semiconductor device, comprising:
a semiconductor die and an encapsulating substrate that together form a support surface that includes an active surface of the die and an adjacent surface of the encapsulating substrate;
a first electrical insulating layer that selectively coats the support surface so that bonding pads on the active surface of the die are exposed through access apertures in the first electrical insulating layer;
electrically conductive runners respectively connected to the die bonding pads through the access apertures and insulated from the active surface by the first electrical insulating layer, wherein the runners are formed from a metallic powder deposit; and
a further electrical insulating layer that coats the runners so that a mounting area of each runner is exposed through an external connection aperture in the further insulating layer.

12. The semiconductor device of claim 11, further comprising respective solder balls mounted to the mounting areas.

13. The semiconductor device of claim 11, further comprising an external electrically conductive mounting pad in each external connection aperture.

14. The semiconductor device of claim 13, further comprising respective solder balls mounted to each of the external electrically conducting mounting pads.

15. The semiconductor device of claim 13, wherein the external electrically conductive mounting pads protrude from the external connection apertures.

16. The semiconductor device of claim 11, wherein the active surface of the die and an adjacent surface of the encapsulating substrate are co-planar.

17. The semiconductor device of claim 11, wherein the package is a grid array package.

18. The semiconductor device of claim 11, wherein the package is a ball grid array package.

19. The semiconductor device of claim 11, wherein the runners are formed from selective laser sintering of the metallic powder.

20. The semiconductor device of claim 11, wherein the runners are formed from a selective laser melting process of the metallic powder.
